(19) United States
(12) Patent Application Publication
(10) Pub. No.: US 2025/0203959 A1
(43) Pub. Date: Jun. 19, 2025

(54) HETEROGENEOUS TERMINATION STRUCTURES FOR SEMICONDUCTOR DEVICES

(71) Applicant: VIRGINIA TECH INTELLECTUAL PROPERTIES, INC., Blacksburg, VA (US)

(72) Inventors: Yuhao ZHANG, Blacksburg, VA (US); Ming XIAO, Blacksburg, VA (US); Boyan WANG, Blacksburg, VA (US)

(21) Appl. No.: 18/538,792

(22) Filed: Dec. 13, 2023

(51) Int. Cl. H01L 29/06; H01L 29/872

(52) U.S. Cl. CPC H10D 62/106; H10D 8/60

(57) ABSTRACT

A device may include a first semiconductor region of a first conductivity type having a top surface and being formed of a first material. A device may include a second semiconductor region of a second conductivity type and being formed of a second material different from the first material and positioned over the top surface of the first semiconductor region. A device may include a metal layer, at least a portion of which is disposed over the top surface of the first semiconductor region and at least a portion of which is disposed over the second semiconductor region, the metal layer forming a device terminal and having a terminal edge positioned over the second semiconductor region, wherein a charge density of at least a portion of the second semiconductor region decreases with an increase in a lateral distance from the terminal edge of the metal layer.

### STATEMENT REGARDING FEDERALLY SPONSORED RESEARCH OR DEVELOPMENT

This invention was made with government support under grant number ECCS-2100504, awarded by the National Science Foundation. The government has certain rights in the invention.

### TECHNICAL FIELD

This disclosure relates to the semiconductor devices, and in particular to termination structures in semiconductor devices.

### DESCRIPTION OF THE RELATED TECHNOLOGY

The breakdown voltage of power semiconductor devices refers to the maximum voltage that a device can withstand across its terminals without experiencing a breakdown or catastrophic failure. It is a critical parameter in the design and operation of these devices, as exceeding the breakdown voltage can lead to the formation of a conducting path through the device, causing it to lose its ability to control the flow of electrical current.

In power semiconductor devices such as diodes, transistors, and thyristors, the breakdown voltage is a crucial specification that determines the device's reliability and performance. There are different types of breakdown mechanisms, depending on the specific device and its construction. For example, common breakdown mechanisms include avalanche breakdown and Zener breakdown. Avalanche breakdown occurs in devices such as power diodes and some transistors when carriers gain enough energy to create additional charge carriers through collisions, leading to a rapid increase in current. Zener breakdown, on the other hand, is characteristic of devices like Zener diodes and occurs when carriers tunnel through the semiconductor's energy barrier.

Commercial power devices can have operation voltages in the hundreds of volts. Edge termination can be an important factor determining the reverse breakdown voltage of the power devices.

### SUMMARY

In some aspects, the techniques described herein relate to a device, including: a first semiconductor region of a first conductivity type, the first conductivity type being one of a p-type conductivity and a n-type conductivity, the first semiconductor region having a top surface and being formed of a first material; a second semiconductor region of a second conductivity type and being formed of a second material different from the first material, the second conductivity type being different from the first conductivity type and being the other of the p-type conductivity and the n-type conductivity, the second semiconductor region positioned over the top surface of the first semiconductor region, a metal layer, at least a portion of which is disposed over the top surface of the first semiconductor region and at least a portion of which is disposed over the second semiconductor region, the metal layer forming a device terminal and having a terminal edge positioned over the second semiconductor region, wherein a charge density of at least a portion of the second semiconductor region decreases with an increase in a lateral distance from the terminal edge of the metal layer.

In some aspects, the techniques described herein relate to a device, wherein the charge density of the second semiconductor region is defined as sheet charge density of an ionized dopant along a direction normal to the top surface of the first semiconductor region.

In some aspects, the techniques described herein relate to a device, including: an interface semiconductor region formed of the second material and having a doping concentration that is greater than that of the second semiconductor region positioned between the second semiconductor region and the metal layer.

In some aspects, the techniques described herein relate to a device, wherein the second semiconductor region includes a plurality of layers, wherein a lateral width of a first layer is less than a lateral width of a second layer that is nearer to the first semiconductor region, the lateral width being measured as a lateral distance between the terminal edge of the metal layer and a lateral extent of the respective layer of the plurality of layers.

In some aspects, the techniques described herein relate to a device, wherein at least one layer of the plurality of layers has a sidewall with a substantially vertical edge.

In some aspects, the techniques described herein relate to a device, wherein at least two layers of the plurality of layers of the second semiconductor region have the same charge density.

In some aspects, the techniques described herein relate to a device, wherein a charge density of the first layer of the plurality of layers is greater than a charge density of the second layer of the plurality of layers positioned below the first layer.

In some aspects, the techniques described herein relate to a device, wherein a concentration of an ionized dopant in the first layer is greater than that in the second layer.

In some aspects, the techniques described herein relate to a device, wherein a thickness of the first layer is greater than the thickness of the second layer.

In some aspects, the techniques described herein relate to a device, wherein at least one layer of the plurality of layers has a sidewall with a substantially beveled edge.

In some aspects, the techniques described herein relate to a device, wherein at least two layers of the plurality of layers of the second semiconductor region have the same charge density.

In some aspects, the techniques described herein relate to a device, wherein a charge density of the first layer of the plurality of layer is greater than a charge density of the second layer of the plurality of layers positioned below the first layer.

In some aspects, the techniques described herein relate to a device, wherein a concentration of an ionized dopant in the first layer is greater than that in the second layer.

In some aspects, the techniques described herein relate to a device, wherein a thickness of the first layer is greater than the thickness of the second layer.

In some aspects, the techniques described herein relate to a device, wherein the device terminal region makes a Schottky contact with the first semiconductor region.

In some aspects, the techniques described herein relate to a device, further including a third semiconductor region positioned between the device terminal region and both the first semiconductor region and the second semiconductor region, the third semiconductor region having a second conductivity type, the third semiconductor region forming a p-n junction with the first semiconductor region, the third semiconductor region being formed of the same material as the second semiconductor region.

In some aspects, the techniques described herein relate to a device, wherein a concentration of ionized dopant in the second semiconductor region decreases with an increase in the lateral distance from the terminal edge and wherein the second semiconductor region has a substantially vertical sidewall.

In some aspects, the techniques described herein relate to a device, wherein the second semiconductor region includes a single layer and wherein charge density of the second semiconductor region decreases with an increase in distance from the terminal edge in a direction normal to the top surface of the first semiconductor region.

### BRIEF DESCRIPTION OF THE DRAWINGS

FIG. 1 shows a cross-sectional view of a portion of a first example semiconductor device.

FIG. 2 shows a cross-sectional view of a portion of a second example semiconductor device.

FIG. 3 shows a cross-sectional view of a portion of a third example semiconductor device.

FIG. 4 shows a cross-sectional view of a portion of a fourth example semiconductor device.

FIG. 5 shows a cross-sectional view of a portion of a fifth example semiconductor device.

FIG. 6 shows a cross-sectional view of a portion of a sixth example semiconductor device.

FIG. 7 shows a cross-sectional view of a portion of a seventh example semiconductor device.

FIG. 8 shows a cross-sectional view of a portion of an eighth example semiconductor device.

FIG. 9 shows a cross-sectional view of a portion of a ninth example semiconductor device.

FIG. 10 shows a cross-sectional view of a portion of a tenth example semiconductor device.

FIG. 11 shows a cross-sectional view of a portion of an eleventh example semiconductor device.

FIG. 12 shows a cross-sectional view of a portion of a twelfth example semiconductor device.

Like reference numbers and designations in the various drawings indicate like elements.

### DETAILED DESCRIPTION

The various concepts introduced above and discussed in greater detail below may be implemented in any of numerous ways, as the described concepts are not limited to any particular manner of implementation. Examples of specific implementations and applications are provided primarily for illustrative purposes.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure.

Any recited method can be carried out in the order of events recited or in any other order that is logically possible. That is, unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

All publications mentioned herein are incorporated herein by reference to disclose and describe the methods and/or materials in connection with which the publications are cited. The publications discussed herein are provided solely for their disclosure prior to the filing date of the present application. Nothing herein is to be construed as an admission that the present invention is not entitled to antedate such publication by virtue of prior invention. Further, the dates of publication provided herein can be different from the actual publication dates, which can require independent confirmation.

While aspects of the present disclosure can be described and claimed in a particular statutory class, such as the system statutory class, this is for convenience only and one of skill in the art will understand that each aspect of the present disclosure can be described and claimed in any statutory class.

It is also to be understood that the terminology used herein is for the purpose of describing particular aspects only and is not intended to be limiting. Unless defined otherwise, all technical and scientific terms used herein have the same meaning as commonly understood by one of ordinary skill in the art to which the disclosed compositions and methods belong. It will be further understood that terms, such as those defined in commonly used dictionaries, should be interpreted as having a meaning that is consistent with their meaning in the context of the specification and relevant art and should not be interpreted in an idealized or overly formal sense unless expressly defined herein.

It should be noted that ratios, concentrations, amounts, and other numerical data can be expressed herein in a range format. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. Ranges can be expressed herein as from “about” one particular value, and/or to “about” another particular value. Similarly, when values are expressed as approximations, by use of the antecedent “about,” it will be understood that the particular value forms a further aspect. For example, if the value “about 10” is disclosed, then “10” is also disclosed.

When a range is expressed, a further aspect includes from the one particular value and/or to the other particular value. For example, where the stated range includes one or both of the limits, ranges excluding either or both of those included limits are also included in the disclosure, e.g. the phrase “x to y” includes the range from ‘x’ to ‘y’ as well as the range greater than ‘x’ and less than ‘y’. The range can also be expressed as an upper limit, e.g. ‘about x, y, z, or less’ and should be interpreted to include the specific ranges of ‘about x’, ‘about y’, and ‘about z’ as well as the ranges of ‘less than x’, less than y′, and ‘less than z’. Likewise, the phrase ‘about x, y, z, or greater’ should be interpreted to include the specific ranges of ‘about x’, ‘about y’, and ‘about z’ as well as the ranges of ‘greater than x’, greater than y′, and ‘greater than z’. In addition, the phrase “about ‘x’ to ‘y’”, where ‘x’ and ‘y’ are numerical values, includes “about ‘x’ to about ‘y’”.

It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to 5%” should be interpreted to include not only the explicitly recited values of about 0.1% to about 5%, but also include individual values (e.g., about 1%, about 2%, about 3%, and about 4%) and the sub-ranges (e.g., about 0.5% to about 1.1%; about 5% to about 2.4%; about 0.5% to about 3.2%, and about 0.5% to about 4.4%, and other possible sub-ranges) within the indicated range.

As used herein, the terms “about,” “approximate,” “at or about,” and “substantially” mean that the amount or value in question can be the exact value or a value that provides equivalent results or effects as recited in the claims or taught herein. That is, it is understood that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In such cases, it is generally understood, as used herein, that “about” and “at or about” mean the nominal value indicated ±10% variation unless otherwise indicated or inferred. In general, an amount, size, formulation, parameter or other quantity or characteristic is “about,” “approximate,” or “at or about” whether or not expressly stated to be such. It is understood that where “about,” “approximate,” or “at or about” is used before a quantitative value, the parameter also includes the specific quantitative value itself, unless specifically stated otherwise.

Prior to describing the various aspects of the present disclosure, the following definitions are provided and should be used unless otherwise indicated. Additional terms may be defined elsewhere in the present disclosure.

As used herein, “comprising” is to be interpreted as specifying the presence of the stated features, integers, steps, or components as referred to, but does not preclude the presence or addition of one or more features, integers, steps, or components, or groups thereof. Moreover, each of the terms “by”, “comprising,” “comprises”, “comprised of,” “including,” “includes,” “included,” “involving,” “involves,” “involved,” and “such as” are used in their open, non-limiting sense and may be used interchangeably. Further, the term “comprising” is intended to include examples and aspects encompassed by the terms “consisting essentially of” and “consisting of.” Similarly, the term “consisting essentially of” is intended to include examples encompassed by the term “consisting of.

As used herein, the term “and/or” includes any and all combinations of one or more of the associated listed items. Expressions such as “at least one of,” when preceding a list of elements, modify the entire list of elements and do not modify the individual elements of the list.

As used in the specification and the appended claims, the singular forms “a,” “an” and “the” include plural referents unless the context clearly dictates otherwise. Thus, for example, reference to “a proton beam degrader,” “a degrader foil,” or “a conduit,” includes, but is not limited to, two or more such proton beam degraders, degrader foils, or conduits, and the like.

The various concepts introduced above and discussed in greater detail below may be implemented in any of numerous ways, as the described concepts are not limited to any particular manner of implementation. Examples of specific implementations and applications are provided primarily for illustrative purposes.

As used herein, the terms “optional” or “optionally” means that the subsequently described event or circumstance can or cannot occur, and that the description includes instances where said event or circumstance occurs and instances where it does not.

Unless otherwise specified, temperatures referred to herein are based on atmospheric pressure (i.e. one atmosphere).

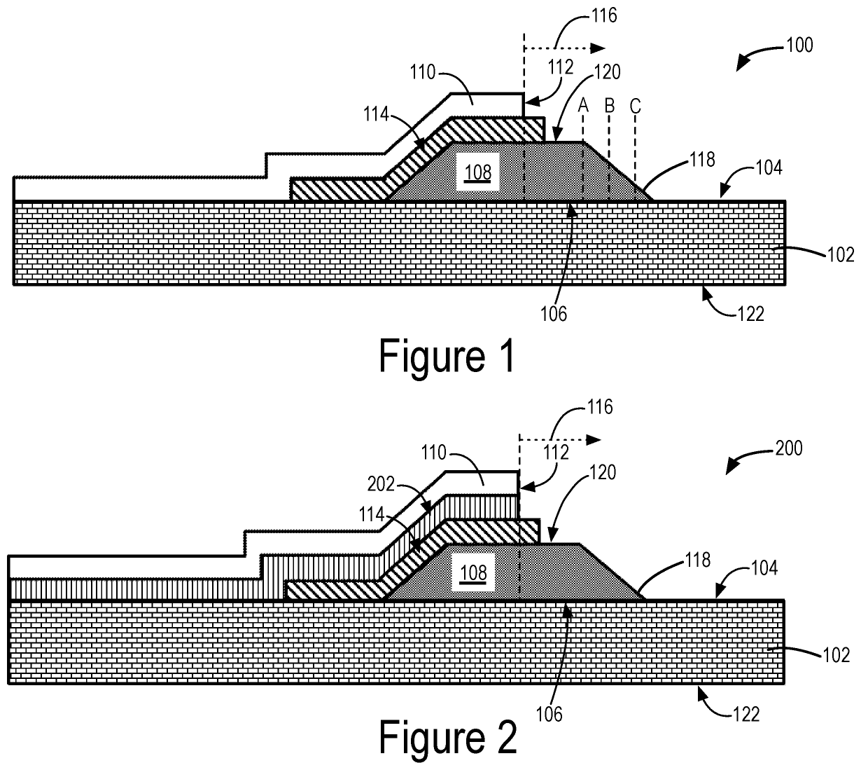

FIG. 1 shows a cross-sectional view of a portion of a first example semiconductor device 100. The first example semiconductor device 100 includes a first semiconductor region 102 of a first conductivity type. The first conductivity type can be one of a p-type conductivity and a n-type conductivity. The first semiconductor region 102 can have a top surface 104 and a bottom surface 106, facing in a direction that is opposite of the direction in which the top surface 104 is facing. The first semiconductor region 102 can be formed of a first material such as, for example, gallium oxide (Ga₂O₃), gallium nitride (GaN), silicon carbide (SiC), aluminum nitride (AlN), diamond, boron nitride (BN), and other wide bandgap semiconductor materials. A second semiconductor region 108 of a second conductivity type can be positioned over the top surface 104 of the first semiconductor region 102. The second semiconductor region 108 has a second conductivity type that is different from the first conductivity type of the first semiconductor region 102. For example, if the first conductivity type of the first semiconductor region 102 is n-type (p-type), then the second conductivity type of the second semiconductor region 108 is p-type (n-type). The second semiconductor region 108 can be formed of a second material that is different from the first material, of which the first semiconductor region 102 is formed. For example, the second material can include semiconductor material such as, for example, nickel oxide (NiO), copper oxide (CuO), zinc oxide (ZnO), gallium nitride (GaN), gallium oxide (Ga₂O₃), aluminum nitride (AlN), diamond, boron nitride (BN), and other wide bandgap semiconductor materials. As the material of the second semiconductor region 108 is different from the material of the first semiconductor region 102 (which in several devices can be the drift region), the first example semiconductor device 100 is a heterogeneous device. In contrast, where the first semiconductor region 102 and the second semiconductor region 108 are formed of the same material, the device would be viewed as homogeneous.

The first example semiconductor device 100 can include a metal layer 110, at least a portion of which is disposed over the top surface 104 of the first semiconductor region 102 and at least a portion of which is disposed over the second semiconductor region 108. The metal layer 110 can form a device terminal of the first example semiconductor device 100. For example, the metal layer 110 can form an anode terminal of the first example semiconductor device 100. The metal layer 110 can have a terminal edge 112 positioned over the second semiconductor region 108. The terminal edge 112 can refer to edge of the metal layer 110 that forms the farthest extent of the metal layer 110 over the first semiconductor region 102 in the lateral direction.

The first example semiconductor device 100 also can include an interface semiconductor region 114 positioned between the second semiconductor region 108 and the metal layer 110. In some examples, at least a portion of the interface semiconductor region 114 can also be positioned between the top surface 104 of the first semiconductor region 102 and the metal layer 110. The interface semiconductor region 114 can be formed of the same material as the second semiconductor region 108, i.e., the second material. Further, the interface semiconductor region 114 can have a doping concentration that is greater than the doping concentration of the second semiconductor region 108. The interface semiconductor region 114 can reduce the risk of high leakage current from the metal layer 110 into the second semiconductor region 108 when the second semiconductor region 108 is depleted. In some examples, the interface semiconductor region 114 can be considered as part of the second semiconductor region 108.

A charge density of at least a portion of the second semiconductor region 108 can decrease with increase in lateral distance from the terminal edge 112. For example, arrow 116 shows the lateral direction from the terminal edge 112. With the increase in distance in this lateral direction from the terminal edge 112, the charge density of at least a portion of the second semiconductor region 108 decreases. FIG. 1 shows three example positions A, B, and C at increasing distances from the terminal edge 112 in the lateral direction. The charge density of the second semiconductor region 108 at position A will be greater than the charge density at position B, which, in turn, will be greater than the charge density at position C. The charge density of the second semiconductor region 108 can be defined as the sheet charge density of ionized dopant along a direction normal to the top surface 104 of the first semiconductor region 102. In particular, the ionized dopants can refer to the acceptor atoms (if p-type) or the donor atoms (if n-type). In some examples, the charge density at position A can be measured by integrating the total ionized dopant (NA or ND, for p-type or n-type, respectively) in the dimension that is normal to the top surface 104 of the first semiconductor region 102. Generally, the sheet charge density can be determined within a plane that is normal to the top surface 104 of the first semiconductor region 102 and normal to the paper and includes the position A. However, if the cross-sectional area of the second semiconductor region 108 in the direction normal to the paper is constant, then the sheet charge density can be determined by integrating along one dimension—the dimension normal to the top surface 104 of the first semiconductor region 102. Thus, the sheet charge density at position A can be determined by the integral of the NA or ND within the second semiconductor region 108 at position A along the direction normal to the top surface 104 of the first semiconductor region 102. Similarly, the sheet charge density of the second semiconductor region 108 at position B can be determined by the integral of the NA or ND within the second semiconductor region 108 at position B along the direction normal to the top surface 104 of the first semiconductor region 102.

In the example shown in FIG. 1, the second semiconductor region 108 has a beveled structure. That is, the second semiconductor region 108 includes a beveled surface 118 that extends between a top surface 120 of the second semiconductor region 108 and the bottom surface 106 of the second semiconductor region 108. Position A is located at the top surface 120 of the second semiconductor region 108, position C is located at a point on the beveled surface 118 close to the bottom surface 106 of the second semiconductor region 108, and position B is located between position A and position C. The distance between the bottom surface 106 and position A in the dimension normal to the top surface 104 of the first semiconductor region 102 is greater than the distance between the bottom surface 106 and position B along the same dimension. Similarly, the distance between the bottom surface 106 and the position C is less than the distance between the bottom surface 106 and the position B in the same dimension. Therefore, an integral of the number of acceptor or donor atoms (NA or ND) at position A will be greater than the integral of the number of acceptor or donor atoms at position B, which, in turn, will be greater than the integral of the number of acceptor or donor atoms at position C all along the dimension that is normal to the top surface 104 of the first semiconductor region 102 (it should be noted that the dimension discussed here can be normal not just to the top surface 104 of the first semiconductor region 102, but can be normal to any other surface that is parallel to the top surface 104 of the first semiconductor region 102 and can include the bottom surface 106 of the second semiconductor region 108 and the top surface 120 of the second semiconductor region 108). Decreasing the charge density of at least a portion of the second semiconductor region 108 with an increase in the lateral distance from the terminal edge 112 can help reduce electric field crowding near the metal layer 110 and thereby improve the breakdown voltage of the first example semiconductor device 100.

In some examples, the beveled surface 118 in the second semiconductor region 108 can be positioned directly below the terminal edge 112. For example, the position A shown in FIG. 1 can be positioned in close proximity (in terms of lateral distance) to the terminal edge 112. This results in a larger proportion of the second semiconductor region 108 contributing to the reduction in electric field crowding.

The beveled surface 118 forms an angle θ with the bottom surface 106 of the second semiconductor region 108. The angle θ can have a value between about 0.1 degrees and about 85 degrees. The rate of decrease in charge density of the second semiconductor region 108 with increase in lateral distance from the terminal edge 112 can be, in part, a function of the angle θ. For example, the rate of decrease in the charge density can be higher with a larger angle θ.

In some examples, the second semiconductor region 108 may not include the beveled surface 118 and instead include a substantially vertical sidewall. As discussed herein, the beveled surface 118 can contribute to the charge density profile of the second semiconductor region 108. That is the beveled surface 118 allows for the decrease in the charge density of the second semiconductor region 108 with increasing distance from the terminal edge 112. In some instances, the decrease in charge density can also be imparted by reducing the number of acceptor or donor atoms (the ionized dopant) in the second semiconductor region 108 with an increase in the lateral distance from the terminal edge 112. That is, the acceptor or donor atom concentration in the second semiconductor region 108 can decrease in as a function of the lateral distance from the terminal edge 112. Thus, the sheet charge density of the second semiconductor region 108 can decrease without a decrease in the height of the second semiconductor region 108. As the acceptor or donor atom concentration is used to provide a reduction in the charge density in the lateral direction, the beveled surface 118 may not be needed, and the second semiconductor region 108 can instead have a substantially vertical sidewall. In some examples, the second semiconductor region 108 can have both the beveled surface 118 and a decrease in the concentration of the ionized dopant with increase in the lateral distance from the terminal edge 112.

While not shown in FIG. 1, the first example semiconductor device 100 can also include a substrate region and a second terminal disposed over a bottom surface 122 of the first semiconductor region 102. For example, the metal layer 110 can serve as an anode and the terminal positioned over the bottom surface 122 of the first semiconductor region 102 can serve as a cathode of a Schottky diode.

The second semiconductor region 108 can form a junction termination extension that can help reduce electric field crowding in the first example semiconductor device 100. The reduction in the electric field crowding in the first example semiconductor device 100 can help increase the breakdown voltage of the first example semiconductor device 100.

FIG. 2 shows a cross-sectional view of a portion of a second example semiconductor device 200. The second example semiconductor device 200 is similar to the first example semiconductor device 100 discussed herein in relation to FIG. 1, in that the second example semiconductor device 200 also includes a second semiconductor region 108. The second example semiconductor device 200 can represent a p-n diode, and to that end, can include a third semiconductor region 202 positioned between the metal layer 110 and both the first semiconductor region 102 and the second semiconductor region 108. In the example shown in FIG. 2, the third semiconductor region 202 can be positioned between the interface semiconductor region 114 and the metal layer 110. The third semiconductor region 202 can have a second conductivity type that is different from the first conductivity type of the first semiconductor region 102. For example, if the first semiconductor region 102 is of the n-type (p-type) conductivity, then the third semiconductor region 202 can be of the p-type (n-type) conductivity. The third semiconductor region 202 can form a p-n junction with the first semiconductor region 102. While not shown in FIG. 2, the second example semiconductor device 200 can include a semiconductor substrate layer and a metal layer disposed over the bottom surface 122 of the first semiconductor region 102. The metal layer 110 and the metal layer disposed over the bottom surface 122 of the first semiconductor region 102 can form the two terminals (anode and cathode) of the second example semiconductor device 200. In some examples, the third semiconductor region 202 can be formed of the same second material as the second semiconductor region 108.

The second semiconductor region 108 and the third semiconductor region 202 can have the same features as the second semiconductor region 108 discussed herein in relation to the first example semiconductor device 100 shown in FIG. 1, in that the charge density of at least a portion of the second semiconductor region 108 decreases with increase in a lateral distance from the terminal edge 112 of the metal layer 110. The second semiconductor region 108 can form a JTE where the decrease in the charge density of the second semiconductor region 108 in the lateral direction from the terminal edge 112 can help reducing electric field crowding in the second example semiconductor device 200 and thereby increase the breakdown voltage of the second example semiconductor device 200.

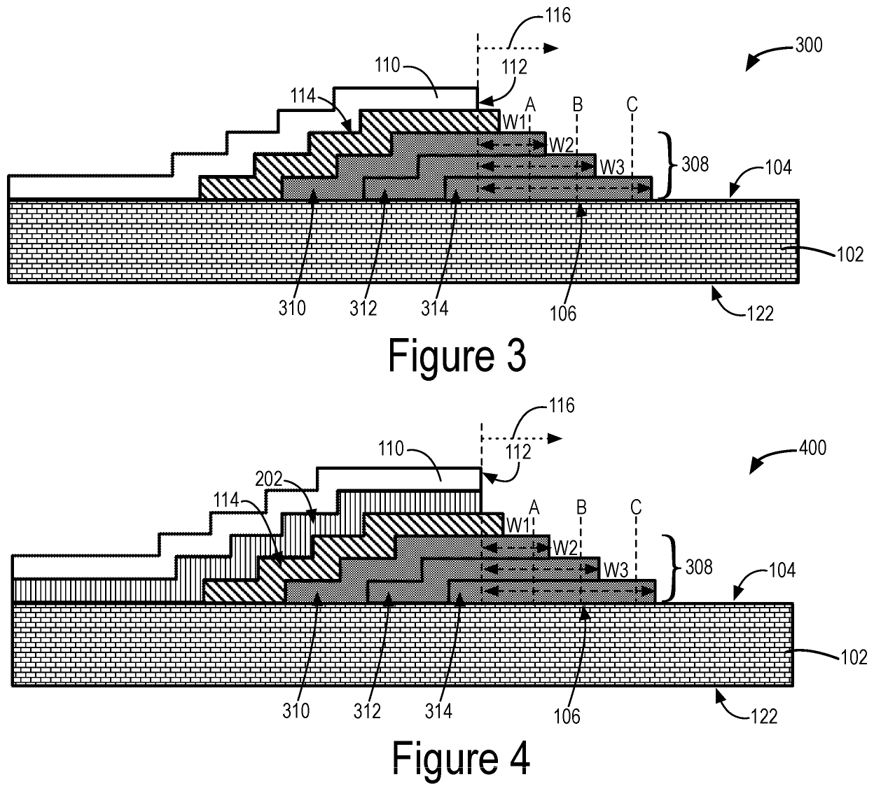

FIG. 3 shows a cross-sectional view of a portion of a third example semiconductor device 300. The third example semiconductor device 300 is similar to the first example semiconductor device 100 discussed herein in relation to FIG. 1 in that like the first example semiconductor device 100, the third example semiconductor device 300 includes the first semiconductor region 102, the metal layer 110 and the interface semiconductor region 114. However, unlike the second semiconductor region 108 in first example semiconductor device 100, which was a single layered semiconductor material, the third example semiconductor device 300 includes a second semiconductor region 308 that includes a plurality of layers. In particular, the second semiconductor region 308 can include a first layer 310, a second layer 312, and a third layer 314 (referred collectively as “a plurality of layers”). The third layer 314 is positioned on the top surface 104 of the first semiconductor region 102, the second layer 312 is positioned, at least in part, over the third layer 314, and the first layer 310 is positioned, at least in part, over the second layer 312. The second semiconductor region 308, similar to the second semiconductor region 108, has a second conductivity type that is different from the first conductivity type of the first semiconductor region 102. The second semiconductor region 308 is also formed of a second material that is different from the first material of the first semiconductor region 102. Also, the second semiconductor region 308 is positioned over the top surface 104 of the first semiconductor region 102.

At least one layer of the plurality of layers of the second semiconductor region 308 can have a sidewall with a substantially vertical edge. For example, the first layer 310, the second layer 312 and the third layer 314 each have a substantially vertical edge. Here vertical is viewed in the direction of the dimension normal to the top surface 104 of the first semiconductor region 102 (or the bottom surface 106 of the second semiconductor region 308).

At least two layers of the plurality of layers of the second semiconductor region 308 can have the same charge density. For example, the first layer 310, the second layer 312 and the third layer 314 can have the same concentration of acceptor or donor atoms. For example, if the second semiconductor region 308 is of n-type conductivity, then the plurality of layers can have the same concentration of donor atoms. Therefore, taken individually, the charge densities of the first layer 310, the second layer 312 and the third layer 314 can be equal when determined in the dimension that is normal to the top surface 104 of the first semiconductor region 102 (or normal to the bottom surface bottom surface 106 of the second semiconductor region 308) assuming that the thicknesses of these layers are the same. The second semiconductor region 308 is configured such that the overall charge density of at least a portion of the second semiconductor region 308 decreases with an increase in a lateral distance from the terminal edge 112 of the metal layer 110. This can be achieved by having layers with widths that get progressively smaller as the layers get closer to the terminal edge 112. Or, in other words, the lateral widths of the layers get larger as the layers get close to the first semiconductor region 102. For example, a lateral width W2 of the second layer 312, which is closer to the terminal edge 112 (measured in the dimension that is normal to the top surface 104 of the first semiconductor region 102) is less than a lateral width W3 of the third layer 314 on account of the second layer 312 being closer to the terminal edge 112 than the third layer 314. Similarly, the lateral width W1 of the first layer 310, which is closer to the terminal edge 112 than the second layer 312, is less than the lateral width W2 of the second layer 312. Said differently, the lateral width W1 of the first layer 310 is less than the lateral width W2 of the second layer 312, where the second layer 312 is nearer to the first semiconductor region 102 than the first layer 310. Further, the lateral width W2 of the second layer 312 is less than the lateral width W3 of the third layer 314, which is nearer to the first semiconductor region 102 than the second layer 312.

The lateral width of each layer of the plurality of layers can be a lateral distance (e.g., in the lateral direction indicated by the arrow 116) between the terminal edge 112 of the metal layer 110 and a lateral extent of the respective layer. As shown in FIG. 3, the lateral extent, in relation to the terminal edge 112, of the second layer 312 is greater than that of the first layer 310, and the lateral extent of the third layer 314 is greater than that of both the second layer 312 and the first layer 310. The increasing lateral widths of the plurality of layers can create a step structure in the second semiconductor region 308. At any position, the charge density of the second semiconductor region 308 can be a sum of the charge densities of each of the layers below that position along the dimension that is normal to the top surface 104 of the first semiconductor region 102. For example, the charge density of the second semiconductor region 308 at position A is the sum of the charge densities of the first layer 310, the second layer 312 and the third layer 314. The charge density of the second semiconductor region 308 at position B is the sum of the charge densities of the second layer 312 and the third layer 314, and the charge density of the second semiconductor region 308 at position C is the charge density of the third layer 314. Thus, the charge density of the second semiconductor region 308 decreases with the increase in the lateral distance from the terminal edge 112.

In some examples, the thickness of each of the plurality of layers of the second semiconductor region 308 can be the same. That is the thickness of the first layer 310 can be equal to the thickness of the third layer 314, which in turn can be equal to the thickness of the third layer 314. With equal thicknesses and equal charge densities of the plurality of layers of the second semiconductor region 308, the change in overall charge density from position A to position B is the same as the change in overall charge density from position B to position C. In some instances, the thicknesses of the layers can be different—resulting in different charge densities associated with the layers. The thickness combined with the doping concentration of a layer can be selected to achieve the desired charge density of each layer.

The second semiconductor region 308 can form a JTE and the decrease in the charge density of the second semiconductor region 308 with an increase in the lateral distance from the terminal edge 112 can help reduce electric field crowding in the third example semiconductor device 300. This can improve the breakdown voltage of the third example semiconductor device 300. While not shown in FIG. 3, the third example semiconductor device 300 can include a substrate layer disposed over the bottom surface 122 of the first semiconductor region 102 and a metal layer disposed over the substrate layer. The metal layer 110 can form one of an anode or cathode terminal of the third example semiconductor device 300 while the metal layer formed over the substrate layer can form the other of the anode or cathode terminal of the third example semiconductor device 300.

FIG. 3 shows that at least a portion of each of the first layer 310, the second layer 312, and the third layer 314 are in contact with the first semiconductor region 102. However this is only an example, in some instances, the third layer 314, which is the bottommost of the plurality of layers of the second semiconductor region 308 can extend all the way to the interface semiconductor region 114, with the second layer 312 deposited over the third layer 314, and the first layer 310 deposited over the second layer 312, thereby having only the third layer 314 be in contact with the first semiconductor region 102. This configuration does not affect the configuration of the plurality of layers at positions A, B, and C.

FIG. 4 shows a cross-sectional view of a portion of a fourth example semiconductor device 400. The fourth example semiconductor device 400 is similar to the third example semiconductor device 300 discussed herein in relation to FIG. 3, in that the fourth example semiconductor device 400 also includes a second semiconductor region 308. The fourth example semiconductor device 400 can represent a p-n diode, and to that end, can include the third semiconductor region 202 positioned between the metal layer 110 and both the first semiconductor region 102 and the second semiconductor region 308. In the example shown in FIG. 4, the third semiconductor region 202 can be positioned between the interface semiconductor region 114 and the metal layer 110. The third semiconductor region 202 can have a second conductivity type that is different from the first conductivity type of the first semiconductor region 102. For example, if the first semiconductor region 102 is of the n-type (p-type) conductivity, then the third semiconductor region 202 can be of the p-type (n-type) conductivity. The third semiconductor region 202 can form a p-n junction with the first semiconductor region 102. While not shown in FIG. 4, the fourth example semiconductor device 400 can include a semiconductor substrate layer and a metal layer disposed over the bottom surface 122 of the first semiconductor region 102. The metal layer 110 and the metal layer disposed over the bottom surface 122 of the first semiconductor region 102 can form the two terminals (anode and cathode) of the second example semiconductor device 200. In some examples, the third semiconductor region 202 can be formed of the same second material as the second semiconductor region 108.

The second semiconductor region 308 and the third semiconductor region 202 can have the same features as the second semiconductor region 308 discussed herein in relation to the third example semiconductor device 300 shown in FIG. 3, in that the charge density of at least a portion of the second semiconductor region 308 decreases with increase in a lateral distance from the terminal edge 112 of the metal layer 110. The decrease in the charge density of the second semiconductor region 108 can help in reducing electric field crowding in the fourth example semiconductor device 400 and thereby increase the breakdown voltage of the fourth example semiconductor device 400.

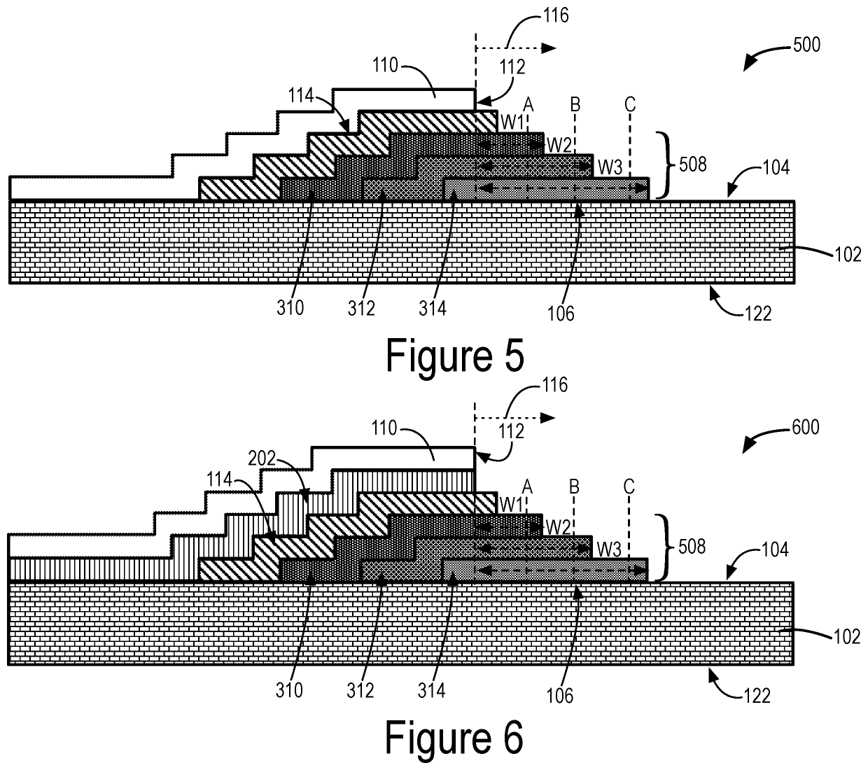

FIG. 5 shows a cross-sectional view of a portion of a fifth example semiconductor device 500. The fifth example semiconductor device 500 is similar to the third example semiconductor device 300 discussed herein in relation to FIG. 3. Like the second semiconductor region 308 of the third example semiconductor device 300, the second semiconductor region 508 of the fifth example semiconductor device 500 also includes a plurality of layers. However, unlike the second semiconductor region 308, where the plurality of the layers had the same charge densities, at least two layers of the plurality of layers of the second semiconductor region 508 can have different charge densities. For example, a charge density of the first layer 310 of the plurality of layers can be greater than a charge density of the second layer 312, which is positioned below the first layer 310. In addition, the charge density of the second layer 312 can be greater than the charge density of the third layer 314, which is positioned below the second layer 312. The dissimilar charge densities of at least two layers of the plurality of layers of the second semiconductor region 508 can provide a different charge density roll-off rate when transitioning between two layers of the second semiconductor region 508 than that provided by the second semiconductor region 308 shown in FIG. 3. For example, the change in charge density from position A to position B in second semiconductor region 308 was substantially equal to the change in charge density from position B to position C (assuming that the thicknesses of the plurality of layers are equal). This is because each of the plurality of layers of the second semiconductor region 308 had the same charge density. In contrast, the change in charge density from position A to position B in second semiconductor region 508 can be different from the change in charge density from position B to position C.

In one example, a difference in charge density between the first layer 310 and the second layer 312 can be greater than the difference in the charge density between the second layer 312 and the third layer 314. In another example, the difference in charge density between the first layer 310 and the second layer 312 can be less than the difference in the charge density between the second layer 312 and the third layer 314. The desired differences in the charge densities of the layers can be achieved by selecting the appropriate combination of doping concentration and thickness for each of the layers. The selected differences in charge densities provide the desired change in charge densities from one position to another (e.g., from position A to position B), and the selected widths of the layers (e.g., W1, W2, and W3) provide the rate (e.g., per unit length in the lateral dimension) at which the charge density reduces in the JTE. In other words, the rate at which the charge density changes per unit length in the lateral direction from the terminal edge 112 can be a function of the charge densities (based on the doping concentrations and thicknesses) of the plurality of layers and the widths of the layers in relation to the terminal edge 112.

Moving in increased distance in the lateral direction from the terminal edge 112, the change in charge density when transitioning from one layer to another nearer to the terminal edge 112 can be greater than the change in charge density when transitioning from one layer to another farther away from the terminal edge 112. In some examples, the difference in charge densities between adjacent layers nearer to the terminal edge 112 can be greater than the difference in charge densities between adjacent layers farther away from the terminal edge 112. For example, the difference in charge densities of the first layer 310 and the second layer 312 can be greater than the difference in charge densities between the second layer 312 and the third layer 314. As a result, transitioning from the first layer 310 to the second layer 312, the change in charge density can be greater than the change in charge density when transitioning from the second layer 312 to the third layer 314. In another example, difference in charge densities between adjacent layers nearer to the terminal edge 112 can be less than the differences in the charge densities between adjacent layers farther away from the terminal edge 112. For example, the difference in the charge densities between the first layer 310 and the second layer 312 can be less than the difference in charge densities between the second layer 312 and the third layer 314. As a result, transitioning from the first layer 310 to the second layer 312, the change in charge density can be less than the change in charge density when transitioning from the second layer 312 to the third layer 314.

In some examples, the differences in the charge densities of at least two layers of the second semiconductor region 508 can be a function of different doping concentrations of the at least two layers. For example, the doping concentration of the first layer 310 can be greater than the doping concentration of the second layer 312, which in turn can be greater than the doping concentration of the third layer 314. As the doping concentration is different for each individual layer, and assuming the thicknesses of the layers is the same, the integral of the ionized dopant (acceptor or donor) will be greater for the first layer 310, than that for the second layer 312 and the third layer 314.

In some examples, the differences in the charge densities of at least two layers of the second semiconductor region 508 can be a function of different thicknesses of the at least two layers. Assuming that the doping concentrations of each of the at least two layers is the same, different thicknesses will result in different charge densities—with thicker layers having higher charge densities than thinner layers.

In some examples, the difference in charge densities of the at least two layers of the second semiconductor region 508 can be a function of combinations of different doping concentrations of the at least two layers and different thicknesses of the at least two layers of the second semiconductor region 508.

The second semiconductor region 508 can form a JTE, and the decrease in the charge density of the second semiconductor region 508 with an increase in the lateral distance from the terminal edge 112 can help reduce electric field crowding in the fifth example semiconductor device 500. This can improve the breakdown voltage of the fifth example semiconductor device 500. While not shown in FIG. 5, the fifth example semiconductor device 500 can include a substrate layer disposed over the bottom surface 122 of the first semiconductor region 102 and a metal layer disposed over the substrate layer. The metal layer 110 can form one of an anode or cathode terminal of the third example semiconductor device 300 while the metal layer formed over the substrate layer can form the other of the anode or cathode terminal of the third example semiconductor device 300. The fifth example semiconductor device 500 can represent a Schottky diode, where the metal layer 110 can form a Schottky contact with the first semiconductor region 102.

FIG. 6 shows a cross-sectional view of a portion of a sixth example semiconductor device 600. The sixth example semiconductor device 600 can represent a p-n diode, where the sixth example semiconductor device 600 includes a third semiconductor region 202 positioned between the metal layer 110 and the second semiconductor region 508. In particular, the third semiconductor region 202 can be positioned between the metal layer 110 and the interface semiconductor region 114. The sixth example semiconductor device 600 is similar to the fifth example semiconductor device 500 discussed herein in relation to FIG. 5. The sixth example semiconductor device 600 includes the second semiconductor region 508 discussed in relation to the fifth example semiconductor device 500. The second semiconductor region 508 can form a JTE, and the reduction in the charge density of the second semiconductor region 508 with an increase in the lateral distance from the terminal edge 112 can help reduce electric field crowding in the sixth example semiconductor device 600, and thereby improve the breakdown voltage of the sixth example semiconductor device 600. While not shown in FIG. 6, the sixth example semiconductor device 600 can include a substrate layer disposed over the bottom surface 122 and a metal layer disposed over the substrate layer. The metal layer 110 and the metal layer disposed over the substrate layer can form the anode and cathode terminals of the p-n diode.

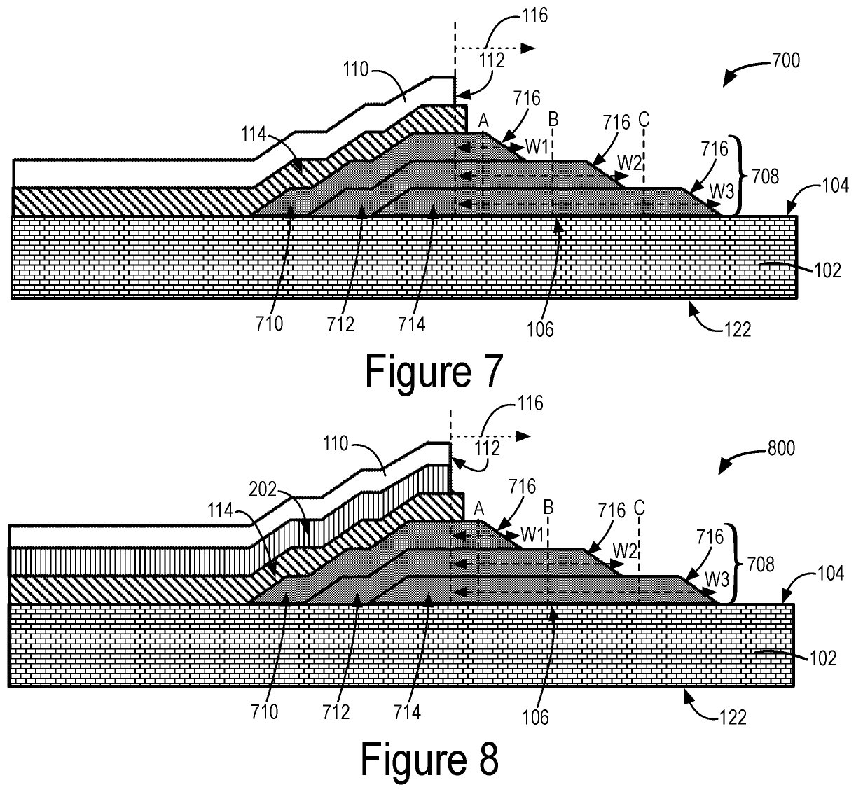

FIG. 7 shows a cross-sectional view of a portion of a seventh example semiconductor device 700. The seventh example semiconductor device 700 is similar to the fifth example semiconductor device 500 discussed herein in relation to FIG. 5. For example, like the fifth example semiconductor device 500, the 700, also includes a second semiconductor region 708 that includes a plurality of layers such as, for example, a first layer 710, a second layer 712, and a third layer 714. The first layer 710, the second layer 712, and the third layer 714 can be similar to the first layer 310, the second layer 312, and the third layer 314, respectively, discussed herein in relation to the fifth example semiconductor device 500. However, unlike the plurality of layers of the second semiconductor region 508, which had substantially vertical edges, the plurality of layers of the second semiconductor region 708 of the seventh example semiconductor device 700 have beveled edges 716. The beveled edges impart a charge density profile in each layer, where the charge density of the layer decreases along the surface of the beveled edges 716 with an increase in the lateral distance from the terminal edge 112. Referring to the FIG. 5, for example, the charge density decreases abruptly between position A and position B by the charge density of the first layer 310. In contrast, because of the beveled edges 716, the charge density decreases gradually between position A and position B. The gradual decrease in the charge density of the second semiconductor region 708 can further help reduce electric field crowding in the seventh example semiconductor device 700. The second semiconductor region 708 forms a JTE that reduces electric filed crowding and improves the breakdown voltage of the seventh example semiconductor device 700. While not shown in FIG. 7, the seventh example semiconductor device 700 can further include a substrate layer disposed over the bottom surface 122 of the first semiconductor region 102 and a metal layer disposed over the substrate layer. The metal layer 110 and the metal layer disposed over the substrate can form anode and cathode terminals of the Schottky diode, where the metal layer 110 forms a Schottky contact with the first semiconductor region 102.

FIG. 8 shows a cross-sectional view of a portion of an eighth example semiconductor device 800. The eighth semiconductor device 800 is similar to the seventh example semiconductor device 700 in that like the seventh example semiconductor device 700 the eighth semiconductor device 800 also includes the second semiconductor region 708 with plurality of layers where at least one layer has a beveled edge. However, unlike the seventh example semiconductor device 700, which is a Schottky diode, the eighth semiconductor device 800 can represent a p-n diode, and can include the third semiconductor region 202 positioned between the metal layer 110 and the second semiconductor region 708, and in particular between the metal layer 110 and the interface semiconductor region 114. While not shown in FIG. 8, the eighth semiconductor device 800 can also include a substrate layer disposed over the bottom surface 122 of the first semiconductor region 102 and a metal layer disposed over the substrate layer. The metal layer 110 and the metal layer disposed over the substrate can form the anode and cathode terminals of the eighth semiconductor device 800. The second semiconductor region 708 forms a JTE which reduces electric field crowding in the eighth semiconductor device 800, and thereby improves the breakdown voltage of the eighth semiconductor device 800.

FIG. 9 shows a cross-sectional view of a portion of a ninth example semiconductor device 900. The ninth semiconductor device 900 can represent a Schottky diode where the metal layer 110 forms a Schottky contact with the first semiconductor region 102. The ninth semiconductor device 900 includes a second semiconductor region 908 having a plurality of layers. Specifically, the second semiconductor region 908 includes a first layer 910, a second layer 912, and a third layer 914. A charge density of the first layer of the plurality of layers is greater than a charge density of the second layer of the plurality of layers positioned below the first layer. Specifically, the charge density of the first layer 910 is greater than the charge density of the second layer 912, which in turn is greater than the charge density of the third layer 914. The first layer 910, the second layer 912, and the third layer 914 can be similar to the first layer 310, the second layer 312, and the third layer 314, respectively, discussed herein in relation to the fifth example semiconductor device 500 in that like the plurality of layers of the second semiconductor region 508, the plurality of layers of second semiconductor region 908 include a first layer that has a charge density that is greater than that of a second layer positioned below the first layer. The second semiconductor region 908 can have similar properties to the second semiconductor region 508 with respect to the charge densities. The second semiconductor region 908 is different from the second semiconductor region 508 of the fifth example semiconductor device 500 in that unlike the plurality of layers of the fifth example semiconductor device 500, which have substantially vertical edges, the plurality of layers of the ninth semiconductor device 900 has beveled edges 716. For example, each of the first layer 910, the second layer 912 and the third layer 914 have beveled edges 716. These beveled edges 716 are similar to the beveled edges 716 discussed herein in relation to the seventh example semiconductor device 700, where each of the first layer 710, second layer 712, and the third layer 714 have beveled edges 716.

Having layers with different charge densities allows a different charge density roll-off rate when transitioning between two layers of the second semiconductor region 908. Having beveled edges 716 provides a gradual change in the charge density when transitioning from one layer to another. Thus, the ninth semiconductor device 900 combines the properties of the second semiconductor region 508 of the fifth example semiconductor device 500 and the second semiconductor region 708 of the seventh example semiconductor device 700.

While not shown in FIG. 9, the ninth semiconductor device 900 can include a substrate layer disposed over the bottom surface 122 of the first semiconductor region 102 and a metal layer disposed over the substrate layer. The metal layer 110 and the metal layer disposed over the substrate can form anode and cathode terminals of the Schottky diode represented by the ninth semiconductor device 900. The second semiconductor region 908 forms a JTE that helps in reducing electric field crowding in the ninth semiconductor device 900 and thereby improve the breakdown voltage of the ninth semiconductor device 900.

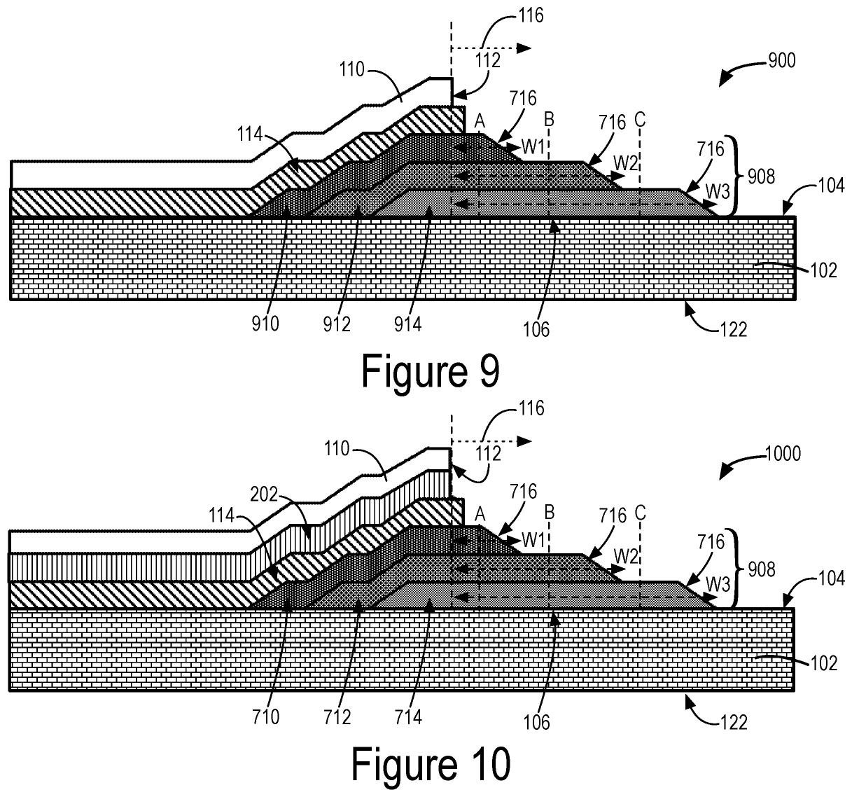

FIG. 10 shows a cross-sectional view of a portion of a tenth example semiconductor device 1000. The tenth semiconductor device 1000 is similar to the ninth semiconductor device 900 discussed herein in relation to FIG. 9. However, unlike ninth semiconductor device 900 which is a Schottky diode, the tenth semiconductor device 1000 is a p-n diode and includes the third semiconductor region 202 positioned between the metal layer 110 and the second semiconductor region 908. Specifically, the third semiconductor region 202 is positioned between the metal layer 110 and the interface semiconductor region 114. The third semiconductor region 202 makes contact with the first semiconductor region 102 to form a p-n junction. While not shown in FIG. 10, the tenth semiconductor device 1000 can include a substrate layer disposed over the bottom surface 122 of the first semiconductor region 102 and a metal layer disposed over the substrate layer. The metal layer 110 and the metal layer disposed over the substrate layer can form the anode and cathode terminals of the p-n diode represented by the tenth semiconductor device 1000. The second semiconductor region 908 forms a JTE that helps in reducing electric field crowding in the tenth semiconductor device 1000 and thereby improving the breakdown voltage of the tenth semiconductor device 1000.

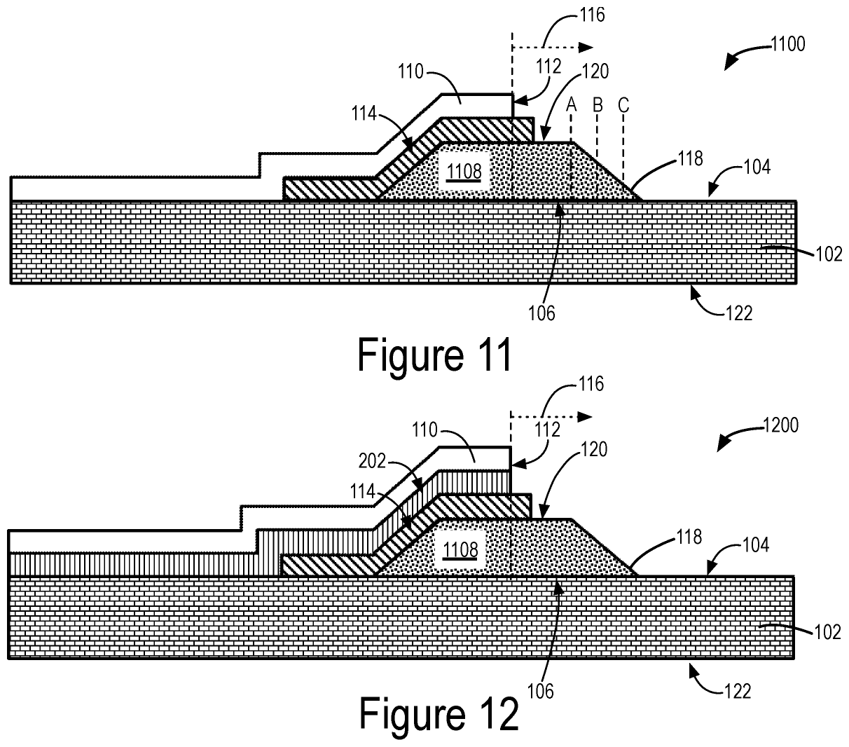

FIG. 11 shows a cross-sectional view of a portion of an eleventh example semiconductor device 1100. The eleventh example semiconductor device 1100 is similar to the first example semiconductor device 100 discussed herein in relation to FIG. 1. However, the eleventh example semiconductor device 1100 includes a second semiconductor region 1108 for which the charge density varies with the distance from the terminal edge 112 in a direction that is normal to the top surface 104 of the first semiconductor region 102. Specifically, the charge density of the second semiconductor region 1108 decreases with an increase in the distance from the terminal edge 112 in a direction that is normal to the top surface 104 of the first semiconductor region 102. This change in charge density profile in combination with the beveled surface 118 can provide a non-linear decrease in the change in the charge density in relation to increasing lateral distance from the terminal edge 112. While not shown in FIG. 11, the eleventh example semiconductor device 1100 can include a substrate layer disposed over the bottom surface 122 of the first semiconductor region 102 and a metal layer disposed over the substrate layer. The metal layer 110 and the metal layer disposed over the substrate layer can form the anode and cathode terminals of the Schottky diode represented by the eleventh example semiconductor device 1100. The second semiconductor region 1108 forms a JTE that helps reducing electric field crowding in the eleventh example semiconductor device 1100 and thereby improving the breakdown voltage of the eleventh example semiconductor device 1100.

FIG. 12 shows a cross-sectional view of a portion of a twelfth example semiconductor device 1200. The twelfth example semiconductor device 1200 is similar to the eleventh example semiconductor device 1100 discussed herein in relation to FIG. 11. However, unlike the eleventh example semiconductor device 1100, which represents a Schottky diode, the twelfth example semiconductor device 1200 represents a p-n diode and includes the third semiconductor region 202 positioned between the metal layer 110 and the interface semiconductor region 114. The third semiconductor region 202 makes contact with the first semiconductor region 102 to form a p-n junction. While not shown in FIG. 12, the twelfth example semiconductor device 1200 can include a substrate layer disposed over the bottom surface 122 of the first semiconductor region 102 and a metal layer disposed over the substrate layer. The metal layer 110 and the metal layer disposed over the substrate layer can form the anode and cathode terminals of the p-n diode represented by the twelfth example semiconductor device 1200. The second semiconductor region 1208 forms a JTE that helps reducing electric field crowding in the twelfth example semiconductor device 1200 and thereby improving the breakdown voltage of the twelfth example semiconductor device 1200.

While FIG. 1-12 discuss JTEs in Schottky and p-n diodes, it should be understood that the JTE described herein can be utilized in other semiconductor devices as well, such as field effect transistors and metal oxide semiconductor field effect transistors to help reduce electric field crowding and help improve breakdown voltage of the semiconductor device.

Additional examples of the processes and devices discussed herein can be found in Wang B., et al. “2.5 kV Vertical Ga₂O₃ Schottky Rectifier with Graded Junction Termination Extension” IEEE Electronics Letters, vol. 44, no. 2, February 2023, and in Xiao M., et al, “NiO Junction Termination Extension for High-Voltage (>3 kV) Ga₂O₃ devices,” Applied Physics Letters, 122 183501 (2023), both of which are incorporated by reference herein in their entirety.

References: All cited references, patent or literature, are incorporated by reference in their entirety. The examples disclosed herein are illustrative and not limiting in nature. Details disclosed with respect to the methods described herein included in one example or embodiment may be applied to other examples and embodiments. Any aspect of the present disclosure that has been described herein may be disclaimed, i.e., exclude from the claimed subject matter whether by proviso or otherwise.
[1] S. J. Pearton, J. Yang, P. H. Cary, F. Ren, J. Kim, M. J. Tadjer, and M. A. Mastro, “A review of Ga2O3 materials, processing, and devices,” Appl. Phys. Rev., vol. 5, no. 1, January 2018, Art. no. 011301, doi: 10.1063/1.5006941.
[2] P. Dong, J. Zhang, Q. Yan, Z. Liu, P. Ma, H. Zhou, and Y. Hao, “6 kV/3.4 mΩ-cm² vertical β-Ga2O3 Schottky barrier diode with BV²/R_{on,sp} performance exceeding 1-D unipolar limit of GaN and SiC,” IEEE Electron Device Lett., vol. 43, no. 5, pp. 765-768, May 2022, doi: 10.1109/LED.2022.3160366.
[3] M. Xiao, B. Wang, J. Liu, R. Zhang, Z. Zhang, C. Ding, S. Lu, K. Sasaki, G.-Q. Lu, C. Buttay, and Y. Zhang, “Packaged Ga2O3 Schottky rectifiers with over 60-A surge current capability,” IEEE Trans. Power Electron., vol. 36, no. 8, pp. 8565-8569 August 2021, doi: 10.1109/TPEL.2021.3049966.
[4] B. Wang, M. Xiao, J. Knoll, C. Buttay, K. Sasaki, G.-Q. Lu, C. Dimarino, and Y. Zhang, “Low thermal resistance (0.5 K/W) Ga2O3 Schottky rectifiers with double-side packaging,” IEEE Electron Device Lett., vol. 42, no. 8, pp. 1132-1135 August 2021, doi: 10.1109/LED.2021.3089035.
[5] H. Gong, F. Zhou, X. Yu, W. Xu, F.-F. Ren, S. Gu, H. Lu, J. Ye, and R. Zhang, “70-μm-body Ga2O3 Schottky barrier diode with 1.48 K/W thermal resistance, 59 a surge current and 98.9% conversion efficiency,” IEEE Electron Device Lett., vol. 43, no. 5, pp. 773-776, May 2022, doi: 10.1109/LED.2022.3162393.
[6] A. V. Bolotnikov, P. G. Muzykov, Q. Zhang, A. K. Agarwal, and T. S. Sudarshan, “Junction termination extension implementing drive-in diffusion of boron for high-voltage SiC devices,” IEEE Trans. Electron Devices, vol. 57, no. 8, pp. 1930-1935 July 2010, doi: 10.1109/TED.2010.2051246.
[7] J. Liu, M. Xiao, R. Zhang, S. Pidaparthi, C. Drowley, L. Baubutr, A. Edwards, H. Cui, C. Coles, and Y. Zhang, “Trap-mediated avalanche in large-area 1.2 kV vertical GaN p-n diodes,” IEEE Electron Device Lett., vol. 41, no. 9, pp. 1328-1331 September 2020, doi: 10.1109/LED.2020.3010784.
[8] J. A. Spencer, A. L. Mock, A. G. Jacobs, M. Schubert, Y. Zhang, and M. J. Tadjer, “A review of band structure and material properties of transparent conducting and semiconducting oxides: Ga₂O₃, Al₂O₃, In₂O₃, ZnO, SnO₂, CdO, NiO, CuO, and Sc₂O₃,” Appl. Phys. Rev., vol. 9, no. 1, March 2022, Art. no. 011315, doi: 10.1063/5.0078037.
[9] K. Konishi, K. Goto, H. Murakami, Y. Kumagai, A. Kuramata, S. Yamakoshi, and M. Higashiwaki, “1-kV vertical Ga₂O₃ field-plated Schottky barrier diodes,” Appl. Phys. Lett., vol. 110, no. 10, March 2017, Art. no. 103506, doi: 10.1063/1.4977857.
[10] W. Li, K. Nomoto, Z. Hu, D. Jena, and H. G. Xing, “Field-plated Ga₂O₃ trench Schottky barrier diodes with a BV²/R_{on,sp} of up to 0.95 GW/cm²,” IEEE Electron Device Lett., vol. 41, no. 1, pp. 107-110, January 2020, doi: 10.1109/LED.2019.2953559.
[11] N. Allen, M. Xiao, X. Yan, K. Sasaki, M. J. Tadjer, J. Ma, R. Zhang, H. Wang, and Y. Zhang, “Vertical Ga2O3 Schottky barrier diodes with small-angle beveled field plates: A Baliga's figure-of-merit of 0.6 GW/cm2,” IEEE Electron Device Lett., vol. 40, no. 9, pp. 1399-142 September 2019, doi: 10.1109/LED.2019.2931697.
[12] S. Roy, A. Bhattacharyya, P. Ranga, H. Splawn, J. Leach, and S. Krishnamoorthy, “High-K oxide field-plated vertical (001)-Ga2O3 Schottky barrier diode with Baliga's figure of merit over 1 GW/cm2,” IEEE Electron Device Lett., vol. 42, no. 8, pp. 1140-1143 August 2021, doi: 10.1109/LED.2021.3089945.
[13] C.-H. Lin, Y. Yuda, M. H. Wong, M. Sato, N. Takekawa, K. Konishi, T. Watahiki, M. Yamamuka, H. Murakami, Y. Kumagai, and M. Higashiwaki, “Vertical Ga2O3 Schottky barrier diodes with guard ring formed by nitrogen-ion implantation,” IEEE Electron Device Lett., vol. 40, no. 9, pp. 1487-1490 September 2019, doi: 10.1109/LED.2019.2927790.
[14] Q. He, X. Zhou, Q. Li, W. Hao, Q. Liu, Z. Han, K. Zhou, C. Chen, J. Peng, G. Xu, X. Zhao, X. Wu, and S. Long, “Selective high resistance zones formed by oxygen annealing for β-GaO Schottky diode applications,” IEEE Electron Device Lett., vol. 43, no. 11, pp. 1933-1936 November 2022, doi: 10.1109/LED.2022.3205326.
[15] J. Yang, F. Ren, M. Tadjer, S. J. Pearton, and A. Kuramata, “2300 V reverse breakdown voltage Ga2O3 Schottky rectifiers,” ECS J. Solid State Sci. Technol., vol. 7, no. 5, pp. Q92-Q96, 2018, doi: 10.1149/2.0241805jss.
[16] Y. Kokubun, S. Kubo, and S. Nakagomi, “All-oxide p-n heterojunction diodes comprising p-type NiO and n-type β-Ga₂O₃,” Appl. Phys. Exp., vol. 9, no. 9, August 2016, Art. no. 091101, doi: 10.7567/APEX.9. 091101.
[17] H. H. Gong, X. H. Chen, Y. Xu, F.-F. Ren, S. L. Gu, and J. D. Ye, “A 1.86-kV double-layered NiO/—Ga2O3 vertical p-n heterojunction diode,” Appl. Phys. Lett., vol. 117, no. 2, July 2020, Art. no. 022104, doi: 10.1063/5.0010052.
[18] X. Lu, X. Zhou, H. Jiang, K. W. Ng, Z. Chen, Y. Pei, K. M. Lau, and G. Wang, “1-kV sputtered p-NiO/n-Ga2O3 heterojunction diodes with an ultra-low leakage current below 1 μA/cm2,” IEEE Electron Device Lett., vol. 41, no. 3, pp. 449-452, March 2020, doi: 10.1109/LED.2020.2967418.
[19] Y. Wang, H. Gong, Y. Lv, X. Fu, S. Dun, T. Han, H. Liu, X. Zhou, S. Liang, J. Ye, R. Zhang, A. Bu, S. Cai, and Z. Feng, “2.41 kV vertical P-Nio/n-Ga2O3 heterojunction diodes with a record Baliga's figure-of-merit of 5.18 GW/cm2,” IEEE Trans. Power Electron., vol. 37, no. 4, pp. 3743-3746 April 2022, doi: 10.1109/TPEL.2021.3123940.
[20] J.-S. Li, C.-C. Chiang, X. Xia, T. J. Yoo, F. Ren, H. Kim, and S. J. Pearton, “Demonstration of 4.7 kV breakdown voltage in NiO/β-Ga2O3 vertical rectifiers,” Appl. Phys. Lett., vol. 121, no. 4, July 2022, Art. no. 042105, doi: 10.1063/5.0097564.
[21] W. Hao, Q. He, X. Zhou, X. Zhao, G. Xu, and S. Long, “2.6 kV NiO/Ga2O3 heterojunction diode with superior high-temperature voltage blocking capability,” in Proc. IEEE 34th Int. Symp. Power Semiconductor Devices ICs (ISPSD), May 2022, pp. 105-108, doi: 10.1109/ISPSD49238.2022.9813680.
[22] J. Zhang, P. Dong, K. Dang, Y. Zhang, Q. Yan, H. Xiang, J. Su, Z. Liu, M. Si, J. Gao, M. Kong, H. Zhou, and Y. Hao, “Ultra-wide bandgap semiconductor Ga2O3 power diodes,” Nature Commun., vol. 13, no. 1, p. 390 July 2022, doi: 10.1038/s41467-022-31664-y.
[23] Y. Lv, Y. Wang, X. Fu, S. Dun, Z. Sun, H. Liu, X. Zhou, X. Song, K. Dang, S. Liang, J. Zhang, H. Zhou, Z. Feng, S. Cai, and Y. Hao, “Demonstration of —Ga2O3 junction barrier Schottky diodes with a Baliga's figure of merit of 0.85 GW/cm2 or a 5 A/700 V handling capabilities,” IEEE Trans. Power Electron., vol. 36, no. 6, pp. 6179-6182 June 2021, doi: 10.1109/TPEL.2020.3036442.
[24] H. H. Gong, X. X. Yu, Y. Xu, X. H. Chen, Y. Kuang, Y. J. Lv, Y. Yang, F.-F. Ren, Z. H. Feng, S. L. Gu, Y. D. Zheng, R. Zhang, and J. D. Ye, “β-Ga2O3 vertical heterojunction barrier Schottky diodes terminated with p-NiO field limiting rings,” Appl. Phys. Lett., vol. 118, no. 20, May 2021, Art. no. 202102, doi: 10.1063/5.0050919.
[25] G. Feng, J. Suda, and T. Kimoto, “Space-modulated junction termination extension for ultrahigh-voltage p-i-n diodes in 4H—SiC,” IEEE Trans. Electron Devices, vol. 59, no. 2, pp. 414-418, February 2012, doi: 10.1109/TED.2011.2175486.
[26] S. Nandy, B. Saha, M. K. Mitra, and K. K. Chattopadhyay, “Effect of oxygen partial pressure on the electrical and optical properties of highly (200) oriented p-type Ni1-xO films by DC sputtering,” J. Mater. Sci., vol. 42, no. 14, pp. 5766-5772 July 2007, doi: 10.1007/s10853-006-1153-x.
[27] M. Xiao, Y. Ma, K. Cheng, K. Liu, A. Xie, E. Beam, Y. Cao, and Y. Zhang, “3.3 kV multi-channel AlGaN/GaN Schottky barrier diodes with P—GaN termination,” IEEE Electron Device Lett., vol. 41, no. 8, pp. 1177-1180 August 2020, doi: 10.1109/LED.2020.3005934.
[28] W. Li, D. Saraswat, Y. Long, K. Nomoto, D. Jena, and H. G. Xing, “Near-ideal reverse leakage current and practical maximum electric field in β-Ga2O3 Schottky barrier diodes,” Appl. Phys. Lett., vol. 116, no. 19, May 2020, Art. no. 192101, doi: 10.1063/5.0007715.
[29] Y. Zhang, F. Udrea, and H. Wang, “Multidimensional device architectures for efficient power electronics,” Nature Electron., vol. 5, no. 11, pp. 723-734, November 2022, doi: 10.1038/s41928-022-00860-5.
[30] H. Lawrence and R. M. Warner, “Diffused junction depletion layer calculations,” Bell System Tech. J., The, vol. 39, no. 2, pp. 389-403, March 1960, doi: 10.1002/j.1538-7305.1960.tb01607.x.
[31] Z. Hu, H. Zhou, Q. Feng, J. Zhang, C. Zhang, K. Dang, Y. Cai, Z. Feng, Y. Gao, X. Kang, and Y. Hao, “Field-plated lateral β-Ga2O3 Schottky barrier diode with high reverse blocking voltage of more than 3 kV and high DC power figure-of-merit of 500 MW/cm2,” IEEE Electron Device Lett., vol. 39, no. 10, pp. 1564-1567 October 2018, doi: 10.1109/LED.2018.2868444.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

What is claimed is:

1. A device, comprising:
a first semiconductor region of a first conductivity type, the first conductivity type being one of a p-type conductivity and a n-type conductivity, the first semiconductor region having a top surface and being formed of a first material;
a second semiconductor region of a second conductivity type and being formed of a second material different from the first material, the second conductivity type being different from the first conductivity type and being the other of the p-type conductivity and the n-type conductivity, the second semiconductor region positioned over the top surface of the first semiconductor region,
a metal layer, at least a portion of which is disposed over the top surface of the first semiconductor region and at least a portion of which is disposed over the second semiconductor region, the metal layer forming a device terminal and having a terminal edge positioned over the second semiconductor region,
wherein a charge density of at least a portion of the second semiconductor region decreases with an increase in a lateral distance from the terminal edge of the metal layer.

2. The device of claim 1, wherein the charge density of the second semiconductor region is defined as sheet charge density of an ionized dopant along a direction normal to the top surface of the first semiconductor region.

3. The device of claim 1, comprising:
an interface semiconductor region formed of the second material and having a doping concentration that is greater than that of the second semiconductor region positioned between the second semiconductor region and the metal layer.

4. The device of claim 1, wherein the second semiconductor region includes a plurality of layers, wherein a lateral width of a first layer is less than a lateral width of a second layer that is nearer to the first semiconductor region, the lateral width being measured as a lateral distance between the terminal edge of the metal layer and a lateral extent of the respective layer of the plurality of layers.

5. The device of claim 4, wherein at least one layer of the plurality of layers has a sidewall with a substantially vertical edge.

6. The device of claim 5, wherein at least two layers of the plurality of layers of the second semiconductor region have the same charge density.

7. The device of claim 5, wherein a charge density of the first layer of the plurality of layers is greater than a charge density of the second layer of the plurality of layers positioned below the first layer.

8. The device of claim 7, wherein a concentration of an ionized dopant in the first layer is greater than that in the second layer.

9. The device of claim 7, wherein a thickness of the first layer is greater than the thickness of the second layer.

10. The device of claim 4, wherein at least one layer of the plurality of layers has a sidewall with a substantially beveled edge.

11. The device of claim 10, wherein at least two layers of the plurality of layers of the second semiconductor region have the same charge density.

12. The device of claim 10, wherein a charge density of the first layer of the plurality of layer is greater than a charge density of the second layer of the plurality of layers positioned below the first layer.

13. The device of claim 12, wherein a concentration of an ionized dopant in the first layer is greater than that in the second layer.

14. The device of claim 12, wherein a thickness of the first layer is greater than the thickness of the second layer.

15. The device of claim 1, wherein the device terminal region makes a Schottky contact with the first semiconductor region.

16. The device of claim 1, further comprising a third semiconductor region positioned between the device terminal region and both the first semiconductor region and the second semiconductor region, the third semiconductor region having a second conductivity type, the third semiconductor region forming a p-n junction with the first semiconductor region, the third semiconductor region being formed of the same material as the second semiconductor region.

17. The device of claim 1, wherein a concentration of ionized dopant in the second semiconductor region decreases with an increase in the lateral distance from the terminal edge and wherein the second semiconductor region has a substantially vertical sidewall.

18. The device of claim 1, wherein the second semiconductor region includes a single layer and wherein charge density of the second semiconductor region decreases with an increase in distance from the terminal edge in a direction normal to the top surface of the first semiconductor region.
